(19) United States
(12) Patent Application Publication
(10) Pub. No.: US 2015/0194553 A1
(43) Pub. Date: Jul. 9, 2015

(54) THERMALLY CONDUCTIVE ENCAPSULATE AND SOLAR CELL MODULE COMPRISING THE SAME

(71) Applicant: TAIFLEX SCIENTIFIC CO., LTD., Kaohsiung (TW)

(72) Inventors: FU-MIN WANG, KAOHSIUNG (TW); I-LING TENG, KAOHSIUNG (TW); TSUNG-TAI HUNG, KAOHSIUNG (TW); YU-HSIEN LEE, KAOHSIUNG (TW); TZU-CHING HUNG, KAOHSIUNG (TW); CHEN-HSIN HUANG, KAOHSIUNG (TW)

(73) Assignee: TAIFLEX SCIENTIFIC CO., LTD., Kaohsiung (TW)

(21) Appl. No.: 14/150,101

(22) Filed: Jan. 8, 2014

(51) Int. Cl. H01L 31/048

(52) U.S. Cl. CPC H01L 31/0481

(57) ABSTRACT

A thermally conductive encapsulate comprising a thermally conductive composite layer having a thermal conductivity of 0.5 W/m*K to 8 W/m*K and an adhesive resin layer having a thermal conductivity of 0.05 W/m*K to 0.4 W/m*K is provided. A percentage of a thickness of the adhesive resin layer relative to a total thickness of the thermally conductive encapsulate ranges from 0.1% to 10%, and the thermally conductive encapsulate has an overall thermal impedance less than 0.72° C.-in²/W. Accordingly, the thermally conductive encapsulate not only provides sealing, insulating and adhesive properties, but also effectively dissipates the heat to the environment without increasing the thickness or volume of the solar cell module and without modifying the original encapsulation process, and thereby enhancing the solar cell module's conversion efficiency and increasing its power output.

### BACKGROUND OF THE INVENTION

1. Field of the Invention

The present invention is related to a semiconductor device technology, particularly to a thermally conductive encapsulate and a solar cell module comprising the same.

2. Description of the Prior Arts

A commonly known solar cell module is composed of a transparent substrate, a first sealing resin layer, photoelectric conversion elements, a second sealing resin layer and a back-sheet from the top to bottom. The photoelectric conversion elements are enclosed by the first and the second sealing resin layers to be isolated from the moisture in the exterior environment.

However, the conventional solar cell modules convert merely 14% to 22% of light energy into electricity, and the rest of the energy is reflected to the environment or converted into heat and increases the operating temperature of the solar cell module, thereby decreasing the conversion efficiency of the solar cell module.

To overcome the foregoing problems, an improved solar cell module comprising a heat sink mounted on the back-sheet is provided. With the multiple extension parts of the heat sink, the heat-dissipation area of the solar cell module is increased, thereby reducing the solar cell module's operating temperature. However, the improved solar cell module has several problems:

(1) Modification of original encapsulation process is required, such that the improved solar cell module is not convenient for mass production.

(2) The applicability of the solar cell module is restricted by the increased volume and thickness.

(3) Heat generated from the photoelectric conversion element cannot be transferred to the heat sinks through the second sealing resin layer and the back-sheet since the photoelectric conversion element is enclosed by two sealing resin layer with relatively low thermal conductivity. Therefore, mounting the heat sinks at the exteriors of the solar cell module is useless for reducing the solar cell module's operating temperature.

### SUMMARY OF THE INVENTION

To overcome the foregoing shortcomings, an objective of the present invention is to provide an effective pathway for dissipating the heat of the photoelectric conversion element to the environment, thereby decreasing the solar cell module's operating temperature and enhancing its conversion efficiency and power output as well.

Another objective of the present invention is to mitigate the aging of the interior elements in the solar cell module at the higher operating temperature for long time period instead of increasing the solar cell module's size or modifying the encapsulation process of the solar cell module.

To achieve the foregoing objective, the present invention provides a thermally conductive encapsulate comprising a thermally conductive composite layer and an adhesive resin layer. The thermally conductive composite layer includes a thermoplastic resin and inorganic powders dispersed in the thermoplastic resin in an amount of 10 vol % to 70 vol % based on the volume of the thermally conductive composite layer, and the thermally conductive composite layer has a thermal conductivity ranging from 0.5 W/m*K to 8 W/m*K. Said adhesive resin layer is disposed on the thermally conductive composite layer and has a thermal conductivity ranging from 0.05 W/m*K to 0.4 W/m*K. A percentage of a thickness of the adhesive resin layer relative to a total thickness of the thermally conductive encapsulate ranges from 0.1% to 10%, and the thermally conductive encapsulate comprising the thermally conductive composite layer and the adhesive resin layer has an overall thermal impedance less than 0.72° C.-in²/W.

In accordance with the present invention, the overall thermal impedance of the thermally conductive encapsulate is reduced to less than 0.72° C.-in²/W by controlling (1) the amount of the inorganic powders and (2) the ratio of the adhesive resin layer relative to the thermally conductive composite layer and the adhesive resin layer in thickness at the same time. Hence, applying the thermally conductive encapsulate to a solar cell module is useful for dissipating the heat generated from the photoelectric conversion element, whereby the aging effect of the solar cell module and undesired increase of operating temperature are mitigated, such that the solar cell comprising the thermally conductive encapsulate provides a path of heat dispersed to the heat sink, which improves conversion efficiency and increases power output.

Said total thickness of the thermally conductive encapsulate is directed to the sum of the thermally conductive composite layer's thickness and the adhesive resin layer's thickness.

Preferably, a hot melting process or a wet coating process may be used to form the adhesive resin layer on the thermally conductive composite layer.

Preferably, the amount of the inorganic powders ranges from 20 vol % to 70 vol % based on the volume of the thermally conductive composite layer.

Preferably, the thermoplastic resin of the thermally conductive composite layer has a thermal conductivity from 0.05 W/m*K to 0.4 W/m*K.

Preferably, the total thickness of the thermally conductive encapsulate ranges from 20 micrometers to 600 micrometers.

Preferably, in the thermally conductive encapsulate, the thermally conductive encapsulate has an overall thermal impedance ranging from 0.01° C.-in²/W to 0.72° C.-in²/W. In a more feasible embodiment, the thermally conductive encapsulate has an overall thermal impedance ranging from 0.1° C.-in²/W to 0.72° C.-in²/W.

Preferably, said thermally conductive encapsulate has a volume resistivity higher than 1.0×10¹⁴ Ω*cm, 22 kV/mm of insulation breakdown voltage, an insulation moisture absorption at insulation breakdown voltage (20° C./24 hours) less than 0.1%, a longitudinal shrinkage less than 3% and a transverse shrinkage less than 1.0% (120° C./3 minutes, measured by ASTM D1204).

The present invention also provides a solar cell module, which comprises a transparent substrate, a sealing resin layer, a photoelectric conversion element, a thermally conductive encapsulate as mentioned above and a back-sheet. The sealing resin layer is disposed on the transparent substrate, and the photoelectric conversion element is disposed on the sealing resin layer. The thermally conductive encapsulate is disposed on the photoelectric conversion element and the sealing resin layer, the adhesive resin layer of the thermally conductive encapsulate contacts the photoelectric conversion element, and the back-sheet is disposed on the thermally conductive composite layer of the thermally conductive encapsulate.

Preferably, the solar cell module comprises another thermally conductive composite layer disposed at exteriors of the thermally conductive encapsulate and the back-sheet and in contact with the photoelectric conversion element. Accordingly, heat generated by the photoelectric conversion element is conducted out of the solar cell module by said another thermally conductive composite layer directly or in combination with the thermally conductive composite layer of the thermally conductive encapsulate, such that the operating temperature of the solar cell module can be decreased.

Preferably, the solar cell module comprises a thermally conductive sealant and a metal frame, the metal frame is bonded to exteriors of the transparent substrate, the sealing resin layer, the thermally conductive encapsulate and the back-sheet by the thermally conductive sealant. With this configuration, heat generated by the photoelectric conversion element can be conducted through a dissipation pathway from the thermally conductive composite layer, the thermally conductive sealant and the metal frame and finally out of the solar cell module to decrease the solar cell module's operating temperature.

More preferably, the solar cell module comprises another thermally conductive composite layer disposed between the thermally conductive sealant and the thermally conductive encapsulate and between the thermally conductive sealant and the back-sheet, and said another thermally conductive composite layer is in contact with the photoelectric conversion element. Therefore, heat generated by the photoelectric conversion element also can be conducted to the environment by said another thermally conductive composite layer directly or through a dissipation pathway from the thermally conductive composite layer, the thermally conductive sealant and the metal frame, so as to decrease the solar cell module's operating temperature.

Preferably, said another thermally conductive composite layer comprises a thermoplastic resin and inorganic powders dispersed in the thermoplastic resin of said another thermally conductive composite layer in an amount of 10 vol % to 70 vol % based on the volume of said another thermally conductive composite layer, whereby said another thermally conductive composite layer has a thermal conductivity ranging from 0.5 W/m*K to 8 W/m*K. More preferably, the amount of the inorganic powders of said another thermally conductive composite ranges from 20 vol % to 70 vol % based on the volume of said another thermally conductive composite layer.

Preferably, the thermally conductive sealant has a thermal conductivity ranging from 0.05 W/m*K to 0.4 W/m*K.

In accordance with the present invention, the adhesive resin layer includes a thermoplastic resin. Said thermoplastic resin included in the adhesive resin layer, in the thermally conductive composite layer or in said another thermally conductive composite layer may be polyolefins, such as, but not limited to, poly(ethylene-co-propylene), poly(propylene-co-ethylene), polyethylene ionomer, ethylene-ethylene vinyl acetate copolymer or cross-linked polyethylene. More specifically, the thermoplastic resin may be, but not limited to, ethylene-acrylate copolymer resin, ethylene-glycerin copolymer resin, ethylene-vinyl acetate copolymer resin (EVA), polyvinyl butyral (PVB), thermoplastic polyurethane (TPU) or polyethylene-glycidyl methacrylate (EGMA).

Said adhesive resin layer or the sealing resin layer may include an adhesive material such as silicone resin or hot melt adhesive.

Said sealing resin layer has a light transmittance more than 92% and includes a material such as ethylene-acrylate copolymer resin, ethylene-glycerin copolymer resin, ethylene-vinyl acetate copolymer resin, polyvinyl butyral, thermoplastic polyurethane or polyethylene-glycidyl methacrylate.

Said transparent substrate has a light transmittance more than 92%, and may be a glass substrate.

Said photoelectric conversion element may be a monocrystalline silicon cell or a polycrystalline silicon chip.

Said back-sheet is a plastic sheet with good weather resistance and good insulating property, which may be made of polyvinyl fluoride (PVF) or polyethylene terephthalate (PET).

Preferably, the inorganic powders have a median particle size equal to or less than 20 micrometers; more preferably, ranging from 1 micrometer to 20 micrometers.

Even more preferably, the inorganic powders have a median particle size ranging from 1 micrometer to 3 micrometers to be well-dispersed in the thermoplastic resin. Accordingly, a thermally conductive composite layer or another thermally conductive composite layer comprising the inorganic powders obtains a higher thermal conductivity.

Preferably, the inorganic powders may be made of a material such as inorganic oxide, inorganic nitride or any combination thereof. More specifically, the material of the inorganic powders includes aluminum oxide (Al₂O₃), aluminum nitride (AlN), boron nitride (BN), silicon carbide or any combination thereof. More preferably, the material of the inorganic powders is boron nitride or aluminum nitride.

In the encapsulation process of the solar cell module, the substrate, the sealing resin layer, the photoelectric conversion element, the thermally conductive encapsulate and the back-sheet are stacked into a laminated structure, then a metal frame loaded with silicone resin sealant or a hot melt adhesive is used to encapsulate the laminated structure. After installation of a junction box and conductive wires, an encapsulated solar cell module is obtained. Optionally, the substrate, the sealing resin layer, the photoelectric conversion element, the thermally conductive encapsulate and the back-sheet also can be enclosed and sealed by a sealing tape, such as acrylic foaming tape, polyethylene foaming tape or butyl rubber foaming tape, to form a laminated structure, and the laminated structure is then pressed into the metal frame to obtain an encapsulated solar cell module.

In conclusion, the thermally conductive encapsulate is capable of having an overall thermal impedance less than 0.72° C.-in²/W when (1) the amount of the inorganic powders ranges from 10 vol % to 70 vol % based on the volume of the thermally conductive composite layer and (2) the percentage of the adhesive resin layer relative to the thermally conductive composite layer and the adhesive resin layer ranges from 0.1% to 10% in thickness. The thermally conductive encapsulate of the present invention not only provides sealing, insulating and adhesive properties same as the conventional sealing layer, but also dissipates the heat generated from the photoelectric conversion element to the environment effectively without increasing the thickness or volume of the solar cell module and without modifying the original encapsulation process. Accordingly, the decreased operating temperature of the solar cell module is beneficial to mitigate the aging of the interior elements in the solar cell module at the higher operating temperature and to improve the solar cell module's conversion efficiency and power output.

Other objectives, advantages and novel features of the invention will become more apparent from the following detailed description when taken in conjunction with the accompanying drawings and tables.

### BRIEF DESCRIPTION OF THE DRAWINGS

FIG. 1 is a schematic view of Examples 1 to 3 of thermally conductive encapsulates in accordance with the present invention;

FIG. 2 illustrates the thermal conductivities of a conventional sealing layer and the thermally conductive encapsulates of Examples 1 and 3;

FIG. 3 is a schematic view of Examples 4 to 6 of solar cell modules in accordance with the present invention;

FIG. 4 is a schematic view of Example 7 of a solar cell module in accordance with the present invention;

FIG. 5 illustrates the operating temperatures of the solar cell modules of Examples 5 and Comparative example 2 at various solar irradiations; and

FIG. 6 illustrates the power output generated by the solar cell modules of Examples 5 and Comparative example 2 at various solar irradiations.

### DETAILED DESCRIPTION OF THE PREFERRED EMBODIMENTS

Hereinafter, one skilled in the arts can easily realize the advantages and effects of a thermally conductive encapsulate and a solar cell module comprising the same in accordance with the present invention from the following examples and tables. The descriptions proposed herein are just preferable examples for the purpose of illustrations only, not intended to limit the scope of the invention. Various modifications and variations could be made in order to practice or apply the present invention without departing from the spirit and scope of the invention.

### Preparation Examples 1 to 4

### Raw Material

1. Ethylene methacrylic acid resin with a melting index (MI) of 8 at 190° C. and having a thermal conductivity of 0.32 W/m*K, as a thermoplastic resin; and

2. Aluminum oxide powders having a median particle size about 5 micrometers, as inorganic powders.

The ethylene methacrylic acid resin and aluminum oxide powders were mixed by a twin screw extruder with various ratios listed in Table 1 to obtain the thermally conductive composite masterbatches of Preparation examples 1 to 4. The thermal conductivities of thermally conductive composite masterbatches were measured with a thermal conductivity meter according to the ASTM E1461, the results were listed in Table 1.

TABLE 1
the amounts of aluminum oxide (Al₂O₃) and ethylene methacrylic
acid resin (EMA resin) based on the volume of the thermally
conductive resin masterbatch (unit: volume percent (vol %))
and the thermal conductivity of the thermally conductive resin
masterbatch in Preparation examples 1 to 4

| | | | thermal conductivity of |
|---|---|---|---|
| Preparation | amount | amount of | the thermally conductive resin |
| examples No. | of Al₂O₃ | EMA resin | masterbatch |
| 1 | 0 vol % | 100 vol % | 0.32 W/m*K |
| 2 | 40 vol % | 60 vol % | 0.59 W/m*K |
| 3 | 60 vol % | 40 vol % | 0.87 W/m*K |
| 4 | 80 vol % | 20 vol % | 1.51 W/m*K |

As shown in Table 1, the thermal conductivities of the thermally conductive resin masterbatches were increased from 0.32 W/m*K (Preparation example 1) to 1.51 W/m*K (Preparation example 4) as the amounts of the aluminum oxides content increased.

### Comparative Example 1

### Conventional Sealing Layer

In the comparative example, the conventional sealing layer was made of pure EMA resin without any inorganic powders. The pure EMA resin was directly formed into a 15 cm*15 cm and 220 μm-thick conventional sealing layer by blown film extrusion. The thermal impedance of the conventional sealing layer was listed in below Table 2.

### Examples 1 to 3

### Thermally Conductive Encapsulates

The thermally conductive resin masterbatches obtained from Preparation examples 2 to 4 were used to prepare the thermally conductive encapsulates of Examples 1 to 3. Said thermally conductive encapsulates were prepared by a similar method as follows.

A thermally conductive resin masterbatch was formed into a 15 cm*15 cm and 220 μm-thick thermally conductive composite layer by blown film extrusion. Then a 20 μm-thick EGMA resin layer, as an adhesive resin layer, was formed on the thermally conductive composite layer by hot melting, so as to obtain a thermally conductive encapsulate.

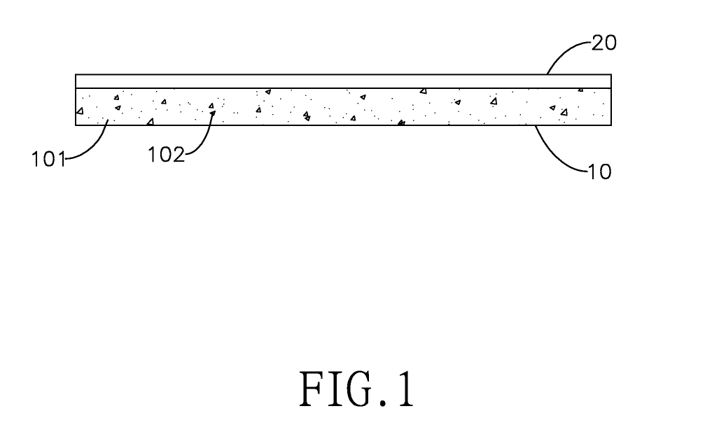

With reference to FIG. 1, the thermally conductive encapsulate prepared from the aforementioned method comprises a thermally conductive composite layer 10 and an adhesive resin layer 20.

The thermally conductive composite layer 10 comprises a thermoplastic resin 101 and multiple inorganic powders 102 dispersed in the thermoplastic resin 101. The adhesive resin layer 20 is disposed on the thermally conductive composite layer 10 and has a thermal conductivity of 0.27 W/m*K.

By means of adding the inorganic powders in the thermally conductive encapsulates of Examples 1 to 3, the thermally conductive encapsulates comprising the thermally conductive composite layers 10 and adhesive resin layers 20 have overall thermal impedances less than 0.72° C.-in²/W, respectively.

TABLE 2
the thermally conductive resin masterbatches used in Examples
1 to 3 and Comparative example 1 and their thermal impedances

| | | the overall thermal |
|---|---|---|
| | thermally conductive resin | impedance of the thermally |
| | masterbatch | conductive encapsulate |
| Comparative | Preparation example 1 | 0.97° C.-in²/W |
| example 1 | | |
| Example 1 | Preparation example 1 | 0.53° C.-in²/W |
| Example 2 | Preparation example 1 | 0.36° C.-in²/W |
| Example 3 | Preparation example 1 | 0.21° C.-in²/W |

### Testing Example 1

### Thermal Conductance of the Thermally Conductive Encapsulate

In the instant testing example, a back-sheet, a thermally conductive encapsulate of Examples 2 or 4 or a conventional sealing layer of Comparative example 1, a sealing resin layer and a transparent glass substrate were stacked in sequence to obtain a laminated sample for determining the thermal conductance of the thermally conductive encapsulate.

To ensure the significance of the experimental results, all laminated samples had identical back-sheet, identical sealing resin layer and identical transparent glass substrate in thickness and in material, and were tested by the same method and under the same environment. Thus, the thermal conductance of the laminated samples was directed to the thermal conductance of the conventional sealing layer and the thermally conductive encapsulate of Examples 1 and 3. Detailed experimental method was as follows.

An identical heat source was mounted on the transparent glass substrates of the laminated samples at a distance of 20 centimeters from each transparent glass substrate to heat the transparent glass substrates in a heating area about 10 square centimeters respectively. The thermal conduction time of each laminated sample was determined by the fact that the conventional sealing layer or the thermally conductive encapsulate started to transfer the thermal energy from the transparent glass substrate to the back-sheet until the temperature of back-sheet was increased to 30° C. The temperature of back-sheet was measured by infrared detector.

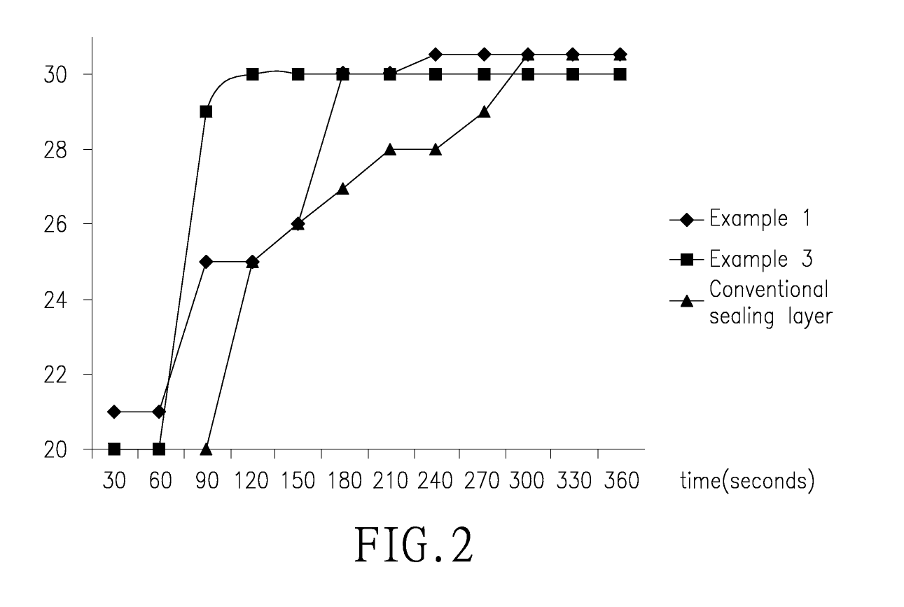

With reference to FIG. 2, the heat conduction time of the conventional sealing layer required almost 300 seconds; however, the thermal conduction time of the thermally conductive encapsulate only required 250 seconds, and even 90 to 100 seconds. It reveals that the thermally conductive encapsulates of Examples 1 and 3 do provide an excellent thermal conductance.

### Examples 4 to 6

### Solar Cell Modules Comprising the Thermally Conductive Encapsulates

The solar cell modules of Examples 4 to 6 respectively comprised the thermally conductive encapsulates of Examples 1 to 3, and all solar cell modules were prepared by a similar method as follows.

First, a transparent glass substrate, an EVA resin layer, an array of 72 monocrystalline silicon cells (purchased by Motech Industries, Inc.), 220 μm-thick thermally conductive encapsulate and polyester series back-sheet were stacked in sequence, the EVA resin layer was pressed at 140° C. for thermal setting until a cross-linking density of 85%, so as to obtain a laminated structure.

Then a thermally conductive silicone resin sealant containing aluminum oxides were injected into the gaps of metal frame to obtain an aluminum frame loaded with the thermally conductive silicon resin sealant.

After that, the laminated structure was enclosed by the aluminum frame loaded with thermally conductive silicone resin sealant and then aged to complete the encapsulation process of the solar cell module.

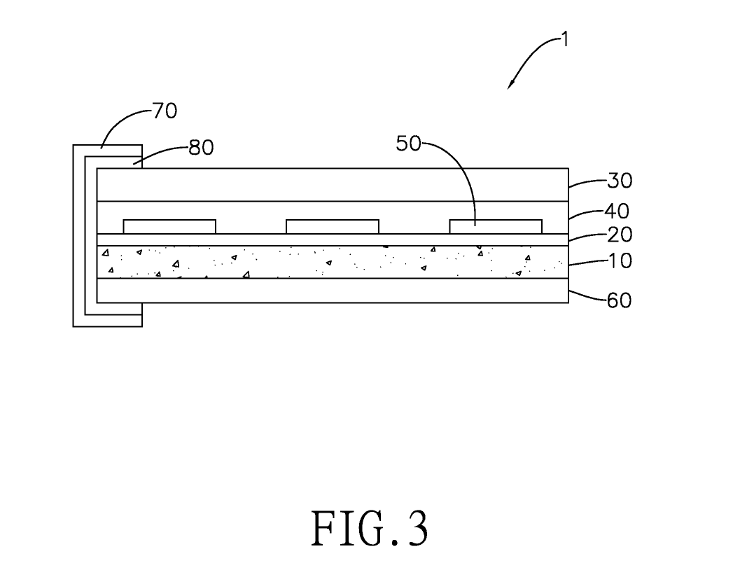

According to the method as mentioned above, the solar cell modules of Examples 4 to 6 have a similar structure as shown in FIG. 3, the difference between the Examples are the materials of the thermally conductive composite layers.

With reference to FIG. 3, the solar cell module 1 comprises a thermally conductive composite layer 10 as shown in FIG. 1, an adhesive resin layer 20, a transparent substrate 30, a sealing resin layer 40, multiple photoelectric conversion elements 50, a back-sheet 60, a metal frame 70 and a thermally conductive sealant 80.

The transparent substrate 30 is a 3 mm-thick transparent glass substrate having a light transmittance more than 92%.

The sealing resin layer 40 is an EVA resin layer, which is disposed on the transparent substrate 30 and has a thickness about 450 micrometers and a thermal conductivity of 0.32 W/m*K.

The photoelectric conversion elements 50 are 72 monocrystalline silicon cells each having a thickness of 180 micrometers and two opposite surfaces. The photoelectric conversion elements 50 are arranged on the sealing resin layer 40 to form an array.

The adhesive resin layer 20 is a 20 μm-thick EGMA resin layer, a portion of the adhesive resin layer 20 is directly adhered to the surface of the photoelectric conversion elements 50, and the rest of the adhesive resin layer 20 is directly adhered to the bottom surface of the sealing resin layer 40 not in contact with the photoelectric conversion elements 50. One surface of each photoelectric conversion element 50 is adhered with the sealing resin layer 40 and the other surface of the photoelectric conversion element 50 is adhered with the adhesive resin layer 20. Accordingly, each and every photoelectric conversion element 50 is sealed by the adhesive resin layer 20 and the sealing resin layer 40, such that the photoelectric conversion elements 50 are fully isolated from the moisture in the external environments.

The thermally conductive composite layer 10 is a composite layer, which is manufactured by EMA resin compound with aluminum oxide powder and has a thickness of 200 micrometers. Said thermally conductive composite layer 10 is attached onto the surface of the adhesive resin layer opposite 20 to the photoelectric conversion elements 50.

The back-sheet 60 is a 350 μm-thick polyester series back-sheet and has a thermal conductivity of 0.28 W/m*K. The thermally conductive composite layer 10 is disposed between the adhesive resin layer 20 and the back-sheet 60.

The metal frame 70 is a heat-dissipation aluminum frame having a groove structure. A thermally conductive sealant 80 is injected into the groove structure of the metal frame 70, and the metal frame 70 is bonded to exteriors of the transparent substrate 30, the sealing resin layer 40, the adhesive rein layer 20, the thermally conductive composite layer 10 and the back-sheet by the thermally conductive sealant 80. Herein, the thermally conductive sealant 80 is made of a silicone resin compound with aluminum oxide and has a thermal conductivity of 1.0 W/m*K.

### Example 7

### Solar Cell Module Comprising the Thermally Conductive Encapsulate

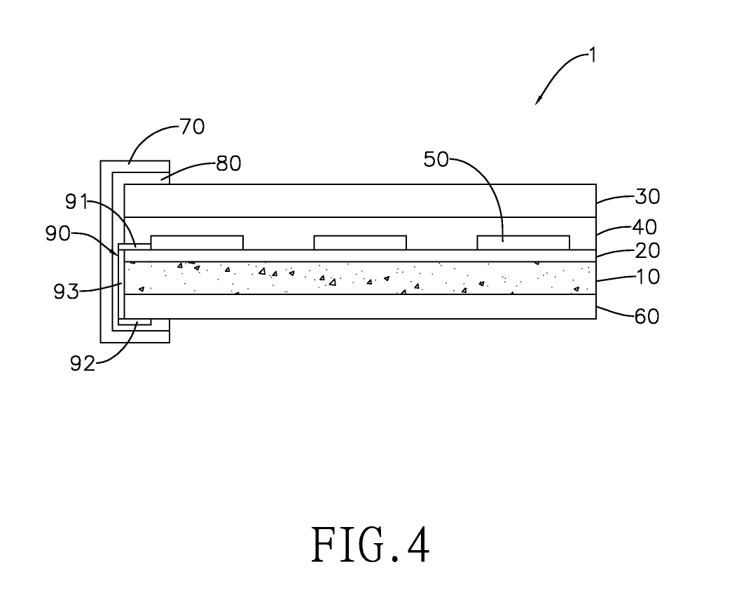

With reference to FIG. 4, the solar cell module 1 has a similar structure with those of Examples 4 to 6 and comprises a thermally conductive composite layer 10, an adhesive resin layer 20, a transparent substrate 30, a sealing resin layer 40, multiple photoelectric conversion elements 50, a back-sheet 60, a metal frame 70 and a thermally conductive sealant 80. The difference between the instant example and the Examples 4 to 6 is that the solar cell module 1 further comprises another thermally conductive composite layer 90, which is made of a material identical to that of the thermally conductive composite layer 10.

Said another thermally conductive composite layer 90 is interposed between the thermally conductive composite layer 10 and the thermally conductive sealant 80, between the adhesive resin layer 20 and the thermally conductive sealant 80, between the thermally conductive sealant 80 and the back-sheet 60, and is in contact with the photoelectric conversion element 50. More specifically, said another thermally conductive composite layer 90 has two thermally conductive extension parts 91, 92 and a thermally conductive main part 93 formed between the thermally conductive extension parts 91, 92. The thermally conductive extension part 91 directly contacts the photoelectric conversion element 50 and is interposed between the sealing resin layer 40 and the adhesive resin layer 20. The thermally conductive main part 93 is mounted on the side surfaces of the thermally conductive encapsulate and of the back-sheet 60, and is interposed between the thermally conductive composite layer 10 and thermally conductive sealant 80, between the adhesive resin layer 20 and the thermally conductive sealant 80, and between the thermally conductive sealant 80 and the back-sheet 60. The thermally conductive main part 93 is interposed between the bottom surface of the back-sheet 60 and the thermally conductive sealant 80.

### Comparative Example 2

### Conventional Solar Cell Module

In the comparative example, a single EVA resin layer is used to replace the thermally conductive composite layer and the adhesive resin layer in the solar cell module of Example 4. Said EVA resin layer is interposed between the photoelectric conversion elements and the back-sheet, and the photoelectric conversion elements are sealed and enclosed by the EVA resin layer and the sealing resin layer. Furthermore, a silicone sealant with a thermal conductivity only 0.36 W/m*K is also used to replace the thermally conductive sealant of Example 4.

### Testing Example 2

### The Operating Temperature of the Solar Cell Module

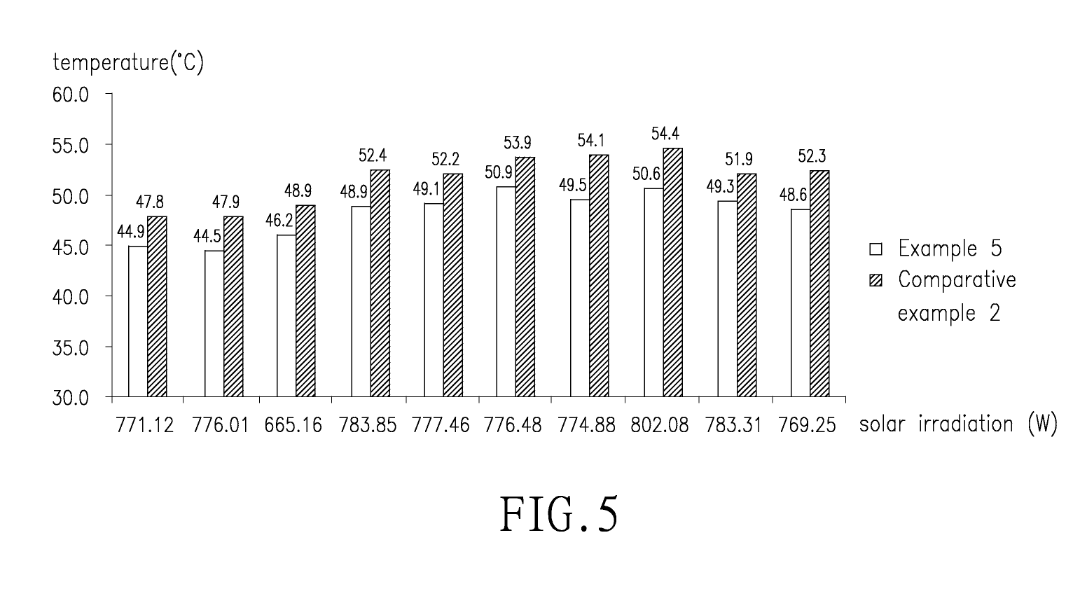

To verify that the thermally conductive encapsulate is useful for reducing the operating temperature of the solar cell module, the solar cell modules of Example 5 and Comparative example 2 were tested exposed to the identical solar irradiation at an ambient temperature of 29° C. to 31° C., and the standard power outputs of the solar cell modules were 230 W per 1.7 square meters. The operating temperatures of the solar cell modules of Example 5 and Comparative example 2 were monitored with an infrared thermometer at various solar irradiations during the time between PM 12:00 and PM 1:00. The experimental results were shown in FIG. 5, every operating temperature as shown in FIG. 5 was obtained from the average of nine experimental results.

FIG. 5 supports that the conventional EVA resin layer with a thermal conductivity of 0.32 W/m*K cannot effectively transfer the thermal energy, which is not converted into the electrical energy, to the adjacent silicone sealant or adjacent back-sheet, thereby failing to dissipate the heat generated from the photoelectric conversion element to the environment. On the contrary, the thermally conductive encapsulate, comprising a thermally conductive composite layer with a thermal conductivity of 0.87 W/m*K and having an overall thermal impedance of 0.36° C.-in²/W, can effectively transfer the thermal energy to the adjacent back-sheet or transfer the thermal energy to the environment through the thermally conductive sealant and the metal frame. Accordingly, the thermally conductive encapsulate does provide a good heat-transfer path to decrease the operating temperature of the solar cell module.

### Testing Example 3

### The Power Output of the Solar Cell Module

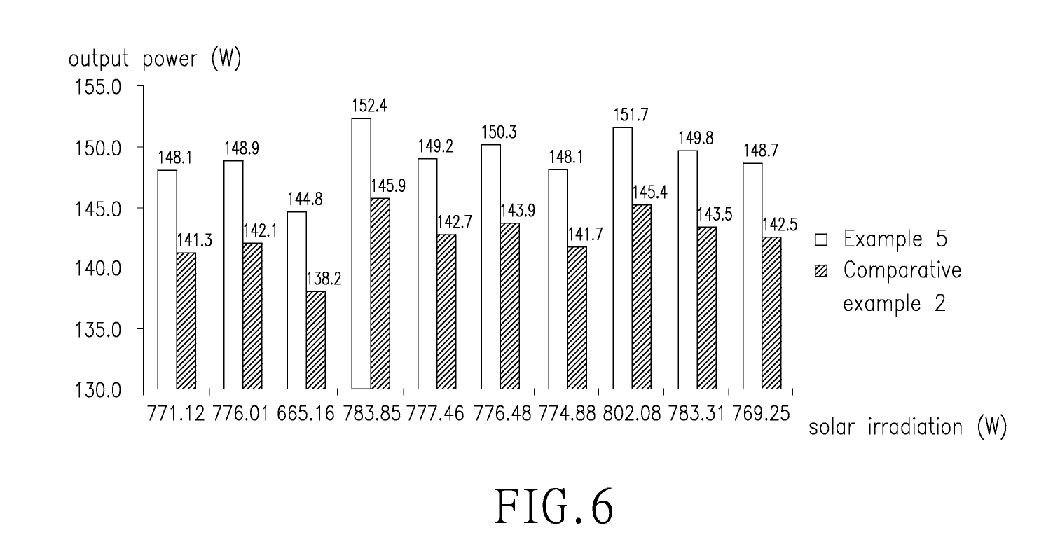

To verify that the thermally conductive encapsulate is useful for improving the solar cell module's power outputs, the solar cell modules of Example 5 and Comparative example 2 were tested under the identical solar irradiation at an ambient temperature of 29° C. to 31° C., and the standard power outputs of the solar cell modules were 230 W per 1.7 square meters. The power outputs of the solar cell modules of Example 5 and Comparative example 2 were monitored with a real-time solar monitoring system at various solar irradiations during the time between PM 12:00 and PM 1:00. The experimental results were shown in FIG. 6.

With reference to FIG. 6, it demonstrates that most solar cell modules' power outputs in Example 5 are 6.4 W higher than those in Comparative example 2 during the time between PM 12:00 and PM 1:00. Moreover, the total power outputs of the solar cell modules in Example 5 is also 4 W higher than that in Comparative example 2.

### Testing Example 4

### The Power Outputs of the Solar Cell Modules

In the testing example, the solar cell modules of Examples 4 to 6 and the conventional solar cell module of Comparative example 2 were tested under 1000 W of solar irradiation at an ambient temperature of 31° C. to 33° C. during the time between AM 10:00 and PM 3:00. The power outputs of the solar cell modules of Examples 4 to 6 and Comparative example 2 were monitored with a real-time solar monitoring system. The experimental results were listed in FIG. 6.

TABLE 3
the theoretical irradiations, maximum power outputs and
total power outputs of the solar cell modules in Examples
4 and 6 and of the conventional solar cell module in
Comparative example 2, and the power output difference
between the samples and Comparative example 2

| | theoretical | | total power output | | |
|---|---|---|---|---|---|
| | irradiation | maximum | during the time | power | |
| Sample | under | power | between AM 10:00 | output | |
| No. | 1000 W | output | and PM 3:00 | difference | |
| Comparative | 235.489 W | 163.9 W | 37418.9 W | 0 | |
| example 2 | | | | | |
| Example 4 | 235.871 W | 164.6 W | 37470.2 W | 51.3 | W |
| Example 6 | 235.711 W | 169.3 W | 37984.1 W | 565.2 | W |

As shown in Table 3, the thermally conductive encapsulate and the thermally conductive sealant can transfer the heat generated by the photoelectric conversion elements to the environment through a lateral pathway from the thermally conductive composite layer, the thermally conductive sealant and the metal frame, thereby improving the heat-dissipating rate and efficiency. Accordingly, all solar cell modules of Examples 4 to 6 have much higher maximum power outputs and much higher total power outputs than those of the Comparative example 2.

In conclusion, the thermally conductive encapsulates of the solar cell modules in Examples 4 to 6 not only dissipate the thermal energy effectively to maintain a lower operating temperature, but also improve the solar cell module's conversion efficiency to allow higher power outputs. Thus, the solar cell module comprising the thermally conductive encapsulate is more applicable in the related field.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

1. A thermally conductive encapsulate, comprising:
a thermally conductive composite layer including a thermoplastic resin and inorganic powders dispersed in the thermoplastic resin in an amount of 40 vol % to 70 vol % based on a volume of the thermally conductive composite layer, the thermally conductive composite layer having a thermal conductivity ranging from 0.5 W/m*K to 8 W/m*K; and
an adhesive resin layer disposed on the thermally conductive composite layer and having a thermal conductivity ranging from 0.05 W/m*K to 0.4 W/m*K;
wherein a percentage of a thickness of the adhesive resin layer relative to a total thickness of the thermally conductive encapsulate ranges from 0.1% to 10%, and the thermally conductive encapsulate has an overall thermal impedance ranging from 0.01° C.*in²/W to 0.72° C.*in²/W.

2. The thermally conductive encapsulate as claimed in claim 1, wherein the thermoplastic resin of the thermally conductive composite layer has a thermal conductivity ranging from 0.05 W/m*K to 0.4 W/m*K.

3. The thermally conductive encapsulate as claimed in claim 1, wherein the inorganic powders have a median particle size equal to or less than 20 micrometers and a material of the inorganic powders includes inorganic oxide, inorganic nitride or any combination thereof.

4: The thermally conductive encapsulate as claimed in claim 3, wherein the material of the inorganic powders includes silicon carbide.

5. (canceled)

6. The thermally conductive encapsulate as claimed in claim 3, wherein the median particle size of the inorganic powders ranges from 1 micrometer to 3 micrometers, and the material of the inorganic powders includes aluminum oxide, aluminum nitride, boron nitride or any combination thereof.

7: The thermally conductive encapsulate as claimed in claim 1, wherein the inorganic powders have a median particle size equal to or less than 20 micrometers and a material of the inorganic powders includes silicon carbide.

8. The thermally conductive encapsulate as claimed in claim 1, wherein the total thickness of the thermally conductive encapsulate ranges from 20 micrometers to 600 micrometers.

9. A solar cell module, comprising:
a transparent substrate;
a sealing resin layer disposed on the transparent substrate;
a photoelectric conversion element disposed on the sealing resin layer;
a thermally conductive encapsulate disposed on the photoelectric conversion element and the sealing resin layer, and comprising:
a thermally conductive composite layer including a thermoplastic resin and inorganic powders dispersed in the thermoplastic resin in an amount of 40 vol % to 70 vol % based on a volume of the thermally conductive composite layer, the thermally conductive composite layer having a thermal conductivity ranging from 0.5 W/m*K to 8 W/m*K; and
an adhesive resin layer disposed between the photoelectric conversion element and the thermally conductive composite layer, and the adhesive resin layer in contact with the photoelectric conversion element and having a thermal conductivity ranging from 0.05 W/m*K to 0.4 W/m*K;
wherein a percentage of a thickness of the adhesive resin layer relative to a total thickness of the thermally conductive encapsulate ranges from 0.1% to 10%, and the thermally conductive encapsulate has an overall thermal impedance ranging from 0.01° C.*in²/W to 0.72° C.*in²/W; and
a back-sheet disposed on the thermally conductive composite layer of the thermally conductive encapsulate.

10. The solar cell module as claimed in claim 9, wherein the thermoplastic resin of the thermally conductive composite layer has a thermal conductivity ranging from 0.05 W/m*K to 0.4 W/m*K.

11. The solar cell module as claimed in claim 9, wherein the inorganic powders have a median particle size equal to or less than 20 micrometers and a material of the inorganic powders includes inorganic oxide, inorganic nitride or any combination thereof.

12. The solar cell module as claimed in claim 11, wherein the material of the inorganic powders includes silicon carbide.

13. (canceled)

14. The solar cell module as claimed in claim 11, wherein the median particle size of the inorganic powders ranges from 1 micrometer to 3 micrometers, and the material of the inorganic powders includes aluminum oxide, aluminum nitride, boron nitride or any combination thereof.

15. The solar cell module as claimed in claim 9, wherein the total thickness of the thermally conductive encapsulate ranges from 20 micrometers to 600 micrometers.

16. The solar cell module as claimed in claim 9, wherein the solar cell module comprises another thermally conductive composite layer disposed at exteriors of the thermally conductive encapsulate and the back-sheet and in contact with the photoelectric conversion element.

17. The solar cell module as claimed in claim 9, wherein the solar cell module comprises a thermally conductive sealant and a metal frame, the metal frame is bonded to exteriors of the transparent substrate, the sealing resin layer, the thermally conductive encapsulate and the back-sheet by the thermally conductive sealant.

18. The solar cell module as claimed in claim 17, wherein the solar cell module comprises another thermally conductive composite layer disposed between the thermally conductive sealant and the thermally conductive encapsulate and between the thermally conductive sealant and the back-sheet, and said another thermally conductive composite layer contacts the photoelectric conversion element.

19. The solar cell module as claimed in claim 17, wherein the thermally conductive sealant has a thermal conductivity ranging from 0.05 W/m*K to 0.4 W/m*K.

20: The solar cell module as claimed in claim 16, wherein said another thermally conductive composite layer comprises a thermoplastic resin and inorganic powders dispersed in the thermoplastic resin of said another thermally conductive composite layer in an amount of 10 vol % to 70 vol % based on the volume of said another thermally conductive composite layer, and said another thermally conductive composite layer has a thermal conductivity ranging from 0.5 W/m*K to 8 W/m*K.
